(19) United States
(12) Patent Application Publication
(10) Pub. No.: US 2010/0035168 A1
(43) Pub. Date: Feb. 11, 2010

(54) PATTERN PREDICTING METHOD, RECORDING MEDIA AND METHOD OF FABRICATING SEMICONDUCTOR DEVICE

(76) Inventors: Fumiharu NAKAJIMA, Kanagawa (JP); Toshiya Kotani, Tokyo (JP); Hiromitsu Mashita, Kanagawa (JP); Chikaaki Kodama, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/537,934

(22) Filed: Aug. 7, 2009

(30) Foreign Application Priority Data
Aug. 8, 2008 (JP) 2008-206005

(51) Int. Cl. G03F 7/00

(52) U.S. Cl. 430/30

(57) ABSTRACT

A pattern predicting method according to one embodiment includes obtaining shape data of a target pattern from shape data of a second pattern to be formed by transferring a first pattern at predetermined process conditions by using a first neutral network, the target pattern being to be a target of the second pattern when the first pattern is transferred at the predetermined process conditions, so as to keep the transferred patterns within an acceptable range, the transferred patterns being formed by transferring the first pattern at process conditions changed from the predetermined process conditions and obtaining shape data of a new first pattern for forming the target pattern at the predetermined process conditions by using a second neutral network.

### CROSS-REFERENCE TO RELATED APPLICATIONS

This application is based upon and claims the benefit of priority from prior Japanese Patent Application No. 2008-206005, filed on Aug. 8, 2008, the entire contents of which are incorporated herein by reference.

### BACKGROUND

Recently, in accordance with miniaturization of a semiconductor device, an optical proximity correction (OPC) technology and a process proximity correction (PPC) technology are proposed, the OPC technology being capable of preventing dimensional variability caused due to a lithography process by correcting a mask pattern and the PPC technology being capable of preventing dimensional variability caused due to a mask process, the lithography process and an etching process by correcting a mask pattern, for example, disclosed in JP-A-1997-319067.

However, it is difficult for the above-mentioned OPC technology and PPC technology to realize the dimension of mask pattern with a high degree of accuracy in terms of variation in process conditions.

### BRIEF SUMMARY

A pattern predicting method according to one embodiment includes obtaining shape data of a target pattern from shape data of a second pattern to be formed by transferring a first pattern at predetermined process conditions by using a first neutral network, the target pattern being to be a target of the second pattern when the first pattern is transferred at the predetermined process conditions, so as to keep the transferred patterns within an acceptable range, the transferred patterns being formed by transferring the first pattern at process conditions changed from the predetermined process conditions and obtaining shape data of a new first pattern for forming the target pattern at the predetermined process conditions.

A computer-readable recording media according to another embodiment includes, a computer program recorded thereon, wherein the computer program is configured to instruct a computer to execute steps of, obtaining shape data of a target pattern from shape data of a second pattern to be formed by transferring a first pattern at predetermined process conditions by using a first neutral network, the target pattern being to be a target of the second pattern when the first pattern is transferred at the predetermined process conditions, so as to keep the transferred patterns within an acceptable range, the transferred patterns being formed by transferring the first pattern at process conditions changed from the predetermined process conditions; and

obtaining shape data of a new first pattern for forming the target pattern at the predetermined process conditions.

A method of fabricating a semiconductor device according to another embodiment includes obtaining the data of the new first pattern by using the pattern predicting method; and forming a device pattern on a wafer by using a mask having the new first pattern obtained.

### BRIEF DESCRIPTION OF THE DRAWING

FIG. 1 is a block diagram schematically showing a configuration of a pattern predicting device according to a first embodiment;

FIG. 2A is an explanatory view schematically showing a configuration of a first neutral network (a first NN);

FIG. 2B is an explanatory view schematically showing a configuration of a second neutral network (a second NN);

FIGS. 3A to 3B are flow charts schematically showing a mask pattern predicting method;

FIG. 4 is an explanatory view schematically showing a main part of circuit pattern in a NAND type flash-memory as a semiconductor device;

FIG. 5 is an explanatory view schematically showing an example of a mask pattern for forming the circuit pattern shown in FIG. 4 on a wafer;

FIGS. 6A to 6B are explanatory views schematically showing two mask patterns having different shapes from each other;

FIGS. 7A to 7B are explanatory views schematically showing examples of wafer patterns formed by actually transferring the mask patterns shown in FIGS. 6A to 6B on a substrate at predetermined process conditions;

FIGS. 8A to 8B are explanatory views schematically showing examples of wafer patterns formed by actually transferring the mask patterns shown in FIGS. 6A to 6B on a substrate at process conditions (1) different from the predetermined process conditions;

FIGS. 9A to 9B are explanatory views schematically showing examples of wafer patterns formed by actually transferring the mask patterns shown in FIGS. 6A to 6B on a substrate at process conditions (2) different from the predetermined process conditions;

FIG. 10 is an explanatory view schematically showing an example of a calculating method of a wafer dimension W mm;

FIG. 11A is an explanatory view schematically showing a learning of the first NN;

FIG. 11B is an explanatory view schematically showing a learning of the second NN;

FIG. 12A is an explanatory view schematically showing a behavior of the first NN; and

FIG. 12B is an explanatory view schematically showing a behavior of the second NN.

### DETAILED DESCRIPTION

### First Embodiment

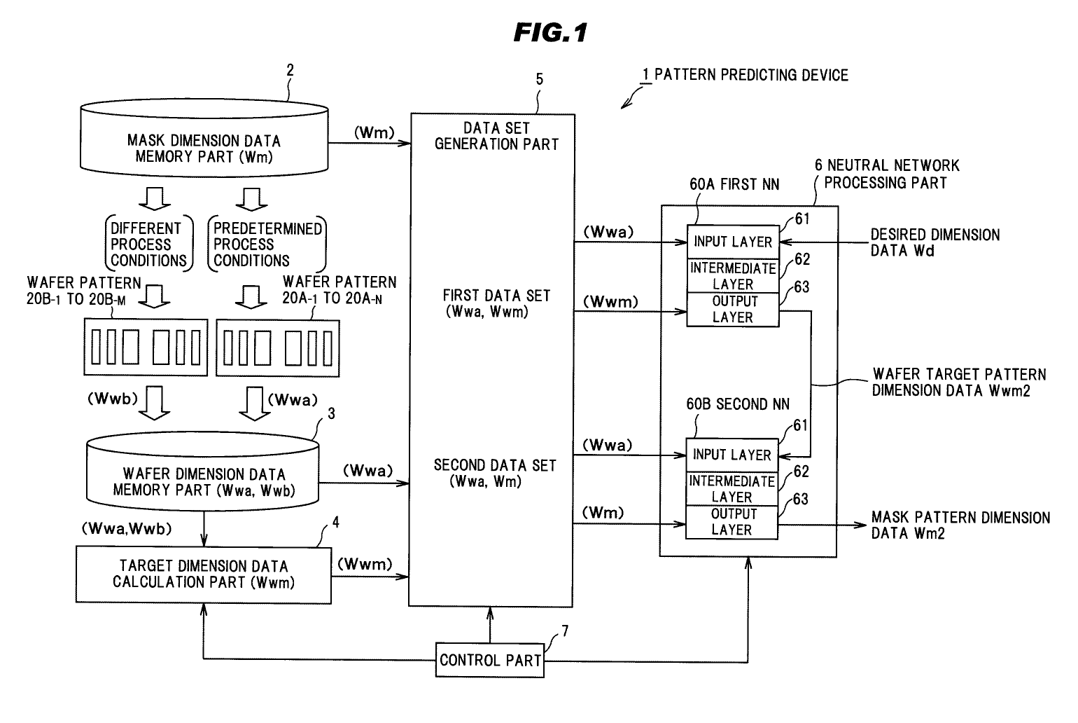

FIG. 1 is a block diagram schematically showing a configuration of a pattern predicting device according to a first embodiment.

The pattern predicting device 1 includes a mask dimension data memory part 2, a wafer dimension data memory part 3, a target dimension data calculation part 4, a data set generation part 5, a neutral network processing part 6 and a control part 7.

The mask dimension data memory part 2 stores dimension data (shape date) Wm of a plurality (for example, N) of mask patterns (first patterns) different in shapes from each other. Here, the mask pattern dimension data are dimension data obtained by calculating actual mask patterns, but dimension data on mask design data can be also used.

Here, “shape data” mean data relating to shapes of patterns, and for example, include at least one of dimension of pattern, distance between patterns, pitch of pattern, contour of pattern, coverage and transmittance. In the embodiment, width dimensions of pattern are used as the shape data.

The wafer dimension data memory part 3 stores dimension data Wwa obtained by measuring N wafer patterns (second patterns) 20A₋₁ to 20A_{-N} formed by transferring the above-mentioned N mask patterns on the substrate at predetermined process conditions and dimension data Wwb obtained by measuring M wafer patterns (third patterns) 20B₋₁ to 20B_{-M} formed by transferring the above-mentioned N mask patterns on the substrate at process conditions different from the predetermined process conditions. Further, the first pattern is not limited to actual mask patterns.

Here, “second pattern” means a pattern that is formed by transferring the first pattern on the substrate at predetermined process conditions. “Third pattern” means a pattern that is formed by transferring the first pattern on the substrate at process conditions different from the predetermined process conditions. Further, the second and third patterns are not limited to the wafer patterns. “Second pattern” and “third pattern” include patterns predicted by simulation based on the first pattern.

“Process conditions” mean conditions corresponding to process (mask process, lithography process or etching process) for forming the second pattern from the first pattern, for example, include strength of electron beam or the like of an electron beam imaging device; shape of illumination, intensity of illumination, degree of polarization, aberration quantity, pupil transmittance distribution, focus value, dose or the like of an exposure device; material of resist; film thickness of resist film, diffusion length of acid in resist; development; etching (concentration, temperature, time and the like), film forming conditions in film forming process; slimming conditions in slimming process. “Predetermined process conditions” mean process conditions which become criteria, and can include designed value.

The target dimension data calculation part 4 in the embodiment calculates wafer target pattern dimension data Wwm based on the dimension data Wwa of the wafer pattern 20A₋₁ to 20A_{-N} and the dimension data Wwb of the wafer pattern 20B₋₁ to 20B_{-M}, for example, by using a general target calculating method. The target calculating method will be explained below.

Here, “target pattern” means a pattern that is calculated so as to allow the shape data of the second patterns to be within a range of variation of process conditions and that is to be a target of the second pattern.

The neutral network processing part 6 includes a first neutral network (hereinafter omitted as “first NN”) 60A and a second neutral network (hereinafter omitted as “second NN”) 60B.

The first NN 60A calculates the wafer target pattern dimension data Wwm2 from desired wafer pattern (design pattern) dimension data Wd.

The second NN 60B calculates mask pattern dimension data Wm2 from wafer target pattern dimension data Wwm2 obtained by the first NN 60A.

The data set generation part 5 generates first data set (Wwa, Wwm) for allowing the first NN 60A to learn and second data set (Wwa, Wm) for allowing the second NN 60B to learn.

The control part 7 in the embodiment includes a learning mode for allowing the first and second NN 60A, 60B to learn so as to develop the first and second NN 60A, 60B and an operating mode for operating the first and second NN 60A, 60B after the learning mode is carried out so as to predict the shapes of the mask pattern, and controls each part of the device 1 corresponding to the learning mode and the operating mode.

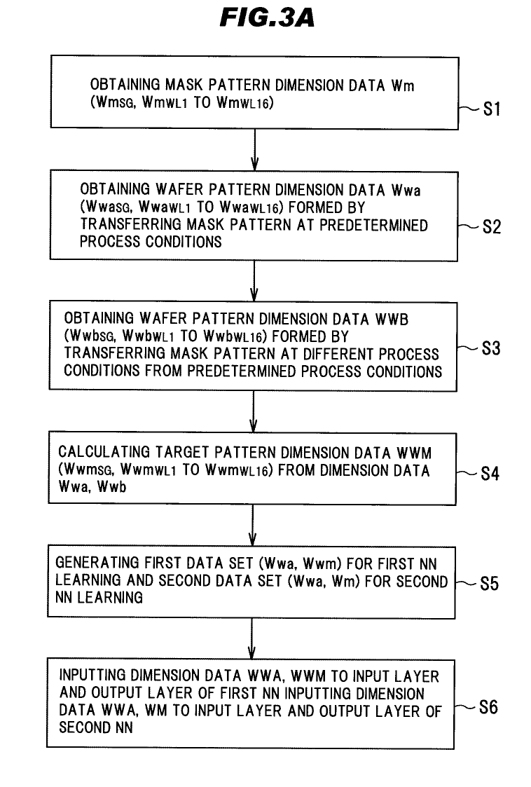

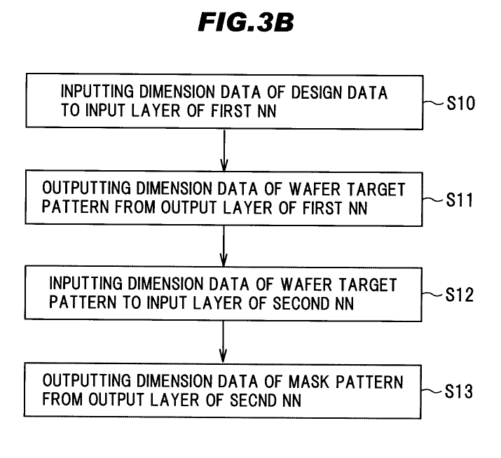

The above-mentioned target dimension data calculation part 4, the data set generation part 5, the neutral network processing part 6 and the control part 7 are configured with a CPU and a memory for storing a CPU program shown in FIGS. 3A, 3B below and various data. Further, a part or the whole of the target dimension data calculation part 4, the data set generation part 5, the neutral network processing part 6 and the control part 7 can be configured with hardware such as an application specific IC (ASIC).

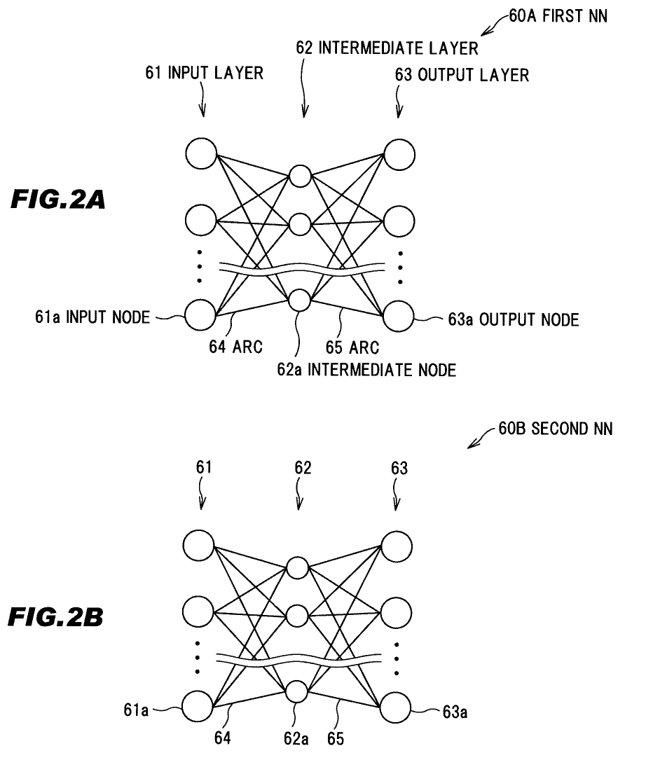

FIG. 2A shows a configuration of the first NN and FIG. 2B shows a configuration of the second NN. The first and second NN 60A, 60B include an input layer 61 including a plurality of input nodes 61a, an intermediate layer 62 including a plurality of intermediate nodes 62a connected to each of the input nodes 61a by network via arcs 64, and an output layer 63 including a plurality of output nodes 63a connected to each of the intermediate nodes 62a by network via arcs 65.

Load values are set to each of the arcs 64, 65 by carrying out the learning mode, the load values showing connection strength among the respective nodes 61a, 62a, 63a.

In the first NN 60A of the embodiment, when the operation mode is carried out, dimension data of each part constituting the desired wafer pattern (design pattern) are inputted to each of the input nodes 61a, and dimension data of each part constituting the wafer target pattern are outputted from the output nodes 63a.

In the second NN 60B of the embodiment, when the operation mode is carried out, dimension data of each part constituting the wafer target pattern are inputted to each of the input nodes 61a, and dimension data of each part constituting the mask pattern are outputted from the output nodes 63a.

### (Mask Pattern Predicting Method)

A mask pattern predicting method using the pattern predicting device 1 shown in FIG. 1 will be explained with reference to FIGS. 3A to 3B, FIG. 4, FIG. 5, FIGS. 6A to 6B, FIGS. 7A to 7B, FIGS. 8A to 8B, FIGS. 9A to 9B, FIG. 10, FIGS. 11A to 11B, and FIGS. 12A to 12B.

FIGS. 3A to 3B are flow charts schematically showing a mask pattern predicting method.

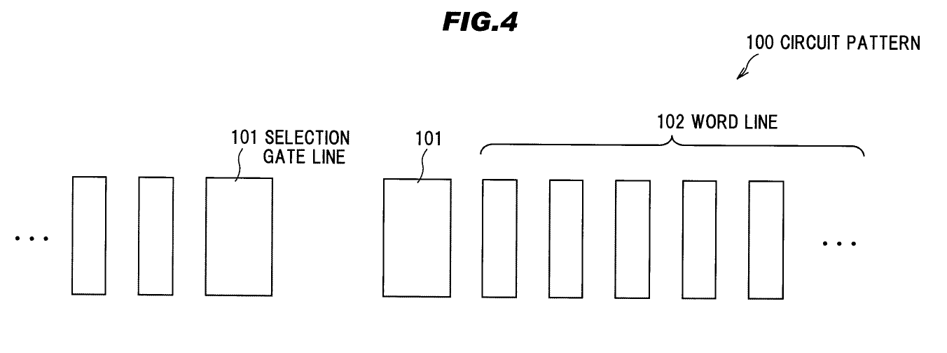

FIG. 4 is an explanatory view schematically showing a main part of circuit pattern as a device pattern in a NAND type flash-memory as a semiconductor device. The NAND type flash-memory is configured to have a structure that NAND cell units in which a plurality (for example, 16) of memory cells connected in series are disposed between a pair of selection transistors are laterally arranged in FIG. 4. Further, the plural NAND cell units can be longitudinally arranged in FIG. 4 and can be also arranged in a matrix shape.

One NAND cell unit in a circuit pattern 100 includes a pair of selection gate lines 101 connected to gates of a pair of selection transistors and sixteen (16) word lines 102 connected to control gates of sixteen (16) memory cells and having a width narrower than that of the selection gate line 101.

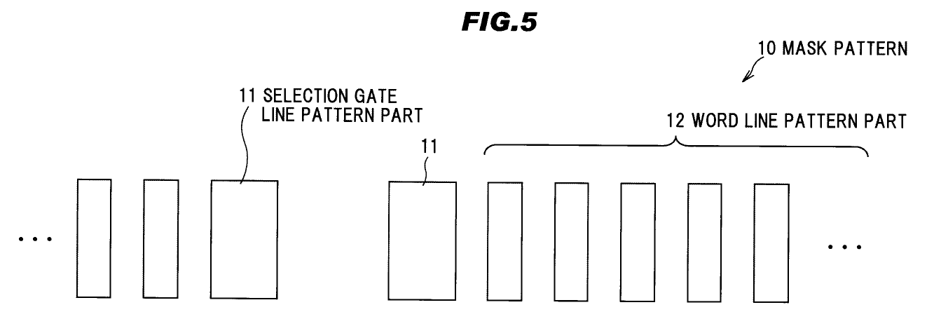

FIG. 5 is an explanatory view schematically showing an example of a mask pattern for forming the circuit pattern shown in FIG. 4 on a wafer. A part of mask pattern 10 corresponding to one NAND cell unit includes a pair of selection gate line pattern parts 11 for forming a pair of selection gate lines 101 and sixteen (16) word line pattern parts 12 for forming sixteen (16) word lines 102.

First, the control part 7 operates the target dimension data calculation part4, data set generation part 5 and neutral network processing part 6 in the learning mode.

### (1) Obtaining Dimension Data Wm

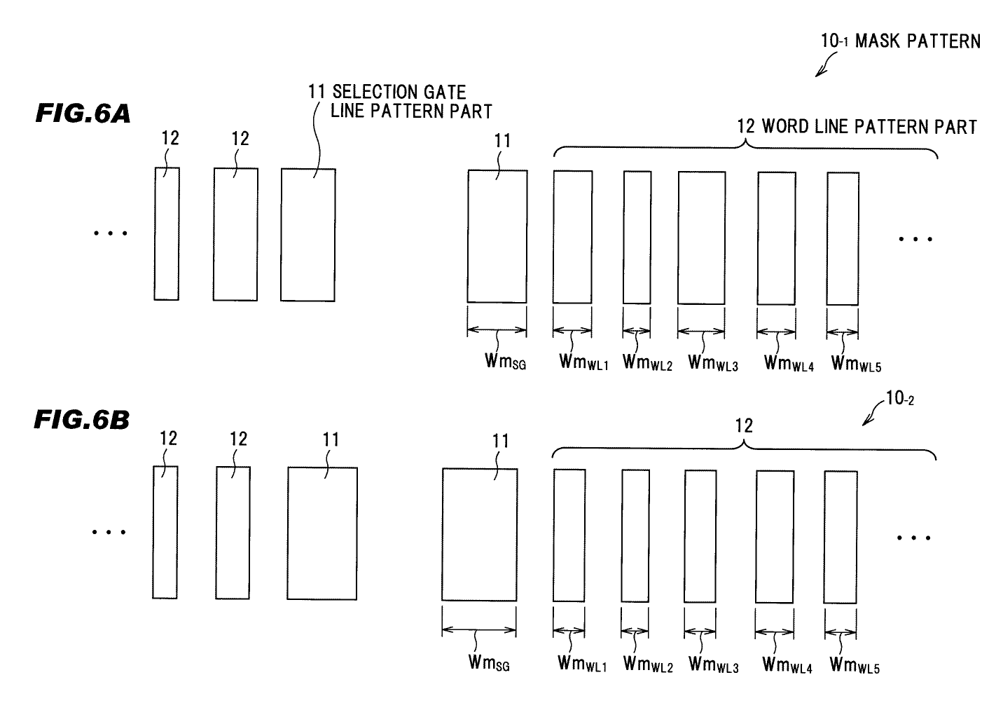

FIGS. 6A to 6B are explanatory views schematically showing two mask patterns having different shapes from each other. The mask dimension data memory part 2 obtains and stores dimension data in case that widths of the selection gate line pattern part 11 and the word line pattern part 12 and a width (space) between the pattern parts 11, 12 are changed (S1). Namely, the memory part 2 stores, relating to a plurality (for example, N) of the mask patterns 10₋₁ to 10_{-N} having different shapes from each other, in terms of symmetric property in right-and-left directions, dimension data Wm_{SG} of width of one selection gate line pattern parts 11 located at the right side or the left side and dimension data (Wm_{WL1} to Wm_{WL16}) of widths of sixteen (16) word line pattern parts 12. Further, the dimension data with the exception of the central portion (for example, almost 8 or 10 line patterns located in the center) to which the peripheral patterns does not affect can be stored in the mask dimension data memory part 2.

Further, in FIG. 5, only widths of the pattern parts and a width (space) between the pattern parts are changed, however, the other characteristic amount in the mask arrangement such as pitch, transmittance, coverage can be also changed.

### (2) Obtaining Dimension Data Wwa

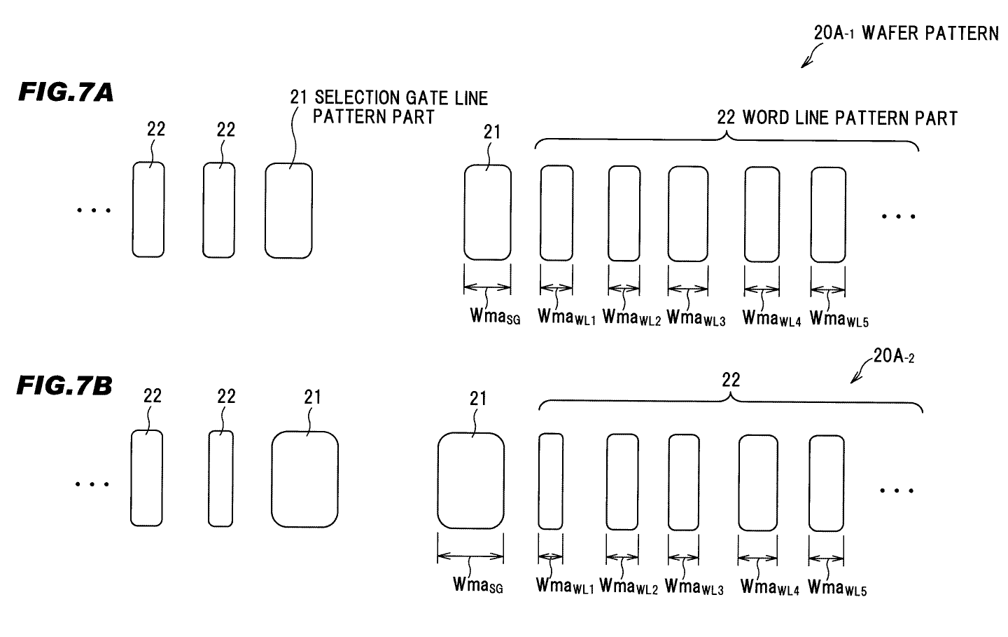

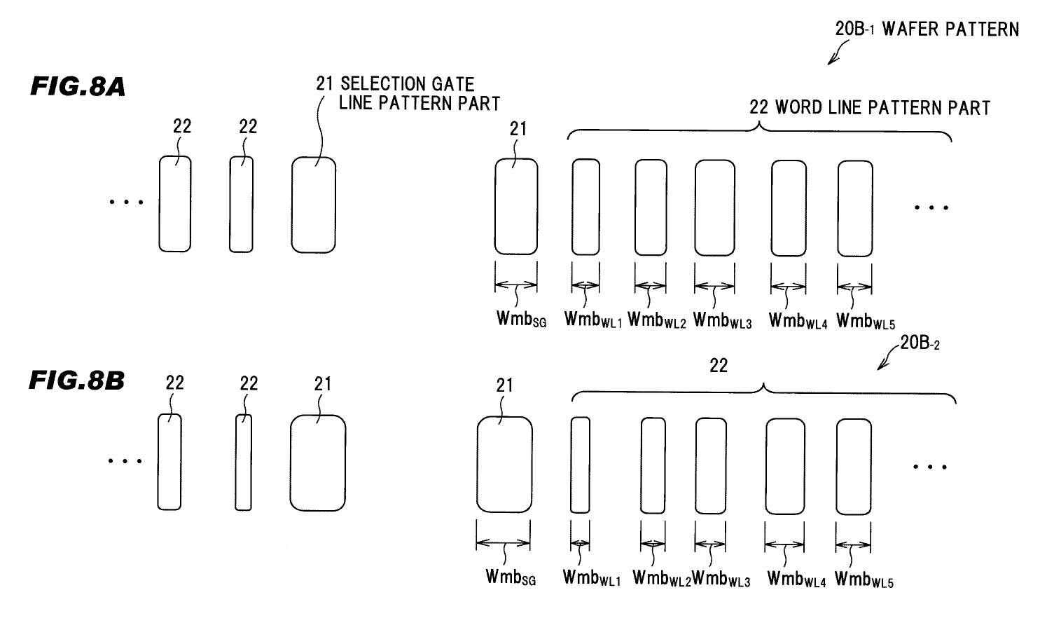

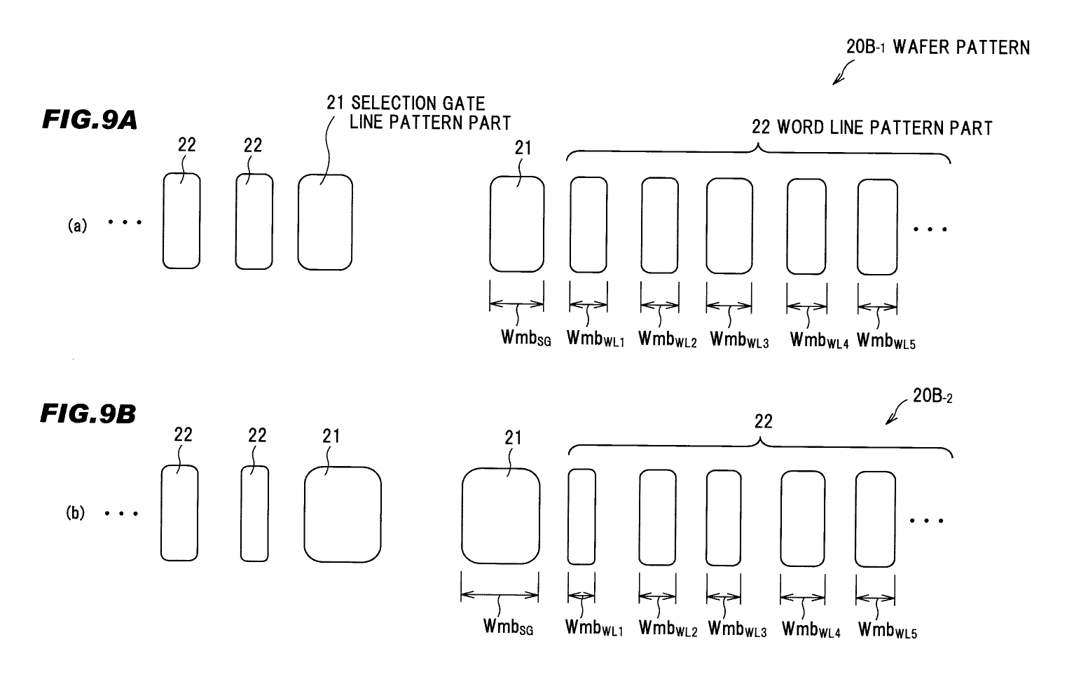

FIGS. 7A to 7B are explanatory views schematically showing examples of wafer patterns formed by actually transferring the mask patterns 10-1, 10-2 shown in FIGS. 6A to 6B on a substrate at predetermined process conditions. FIGS. 8A to 8B are explanatory views schematically showing examples of wafer patterns formed by actually transferring the mask patterns 10-1, 10-2 shown in FIGS. 6A to 6B on a substrate at process conditions (1) different from the predetermined process conditions. FIGS. 9A to 9B are explanatory views schematically showing examples of wafer patterns formed by actually transferring the mask patterns 10-1, 10-2 shown in FIGS. 6A to 6B on a substrate at process conditions (2) different from the predetermined process conditions.

Wafer patterns are formed by actually transferring N mask patterns having different shapes from each other stored in the mask dimension data memory part 2 at the predetermined process conditions, at the process conditions (1), at the process conditions (2), . . . .

As shown in FIGS. 7A to 7B, the wafer patterns 20A₋₁, 20A₋₂ formed at the predetermined process conditions include selection gate line pattern parts 21 and sixteen (16) word line pattern parts 22. Dimension data WwaSG of widths of selection gate line pattern parts 21 and dimension data Wwa_{WL1} to WWa_{WL16} of widths of the word line pattern parts 22 are measured and stored in the wafer dimension data memory part3 (S2).

### (3) Obtaining Dimension Data Wwb

As shown in FIGS. 8A to 8B, the wafer patterns 20B₋₁, 20B₋₂ formed at the process conditions (1) include selection gate line pattern parts 21 and word line pattern parts 22. Dimension data WwbSG of width of one selection gate line pattern part 21 and dimension data Wwb_{WL1} to Wwb_{WL16} of widths of sixteen (16) word line pattern parts 22 are measured and stored in the wafer dimension data memory part3 (S3).

As shown in FIGS. 9A to 9B, the wafer patterns 20B₋₁, 20B₋₂ formed at the process conditions (2) include selection gate line pattern parts 21 and word line pattern parts 22. Dimension data WwbSG of width of one selection gate line pattern part 21 and dimension data Wwb_{WL1} to Wwb_{WL16} of widths of sixteen (16) word line pattern parts 22 are measured and stored in the wafer dimension data memory part3. Similarly, with regard to the wafer patterns formed by actually transferring at the other process conditions (3) . . . different from the predetermined process conditions, dimension data of widths are measured and stored in the wafer dimension data memory part3. This is also applied to the other mask patterns 10₋₃ to 10_{-N}.

### (4) Calculating Wafer Target Pattern Dimension Data Wwm

The target dimension data calculation part 4 calculates the dimension data Wwm of the wafer target pattern in which process tolerance that the shapes (dimensions) of the wafer pattern are kept within the acceptable range even if the process conditions fluctuate is almost the largest value, based on the dimension data Wwa of the wafer pattern formed at the predetermined process conditions and the dimension data Wwb of the wafer pattern formed at the process conditions different from the predetermined process conditions (S4). As a calculating method of the wafer target pattern dimension data Wwm, for example, a general target calculating method can be used.

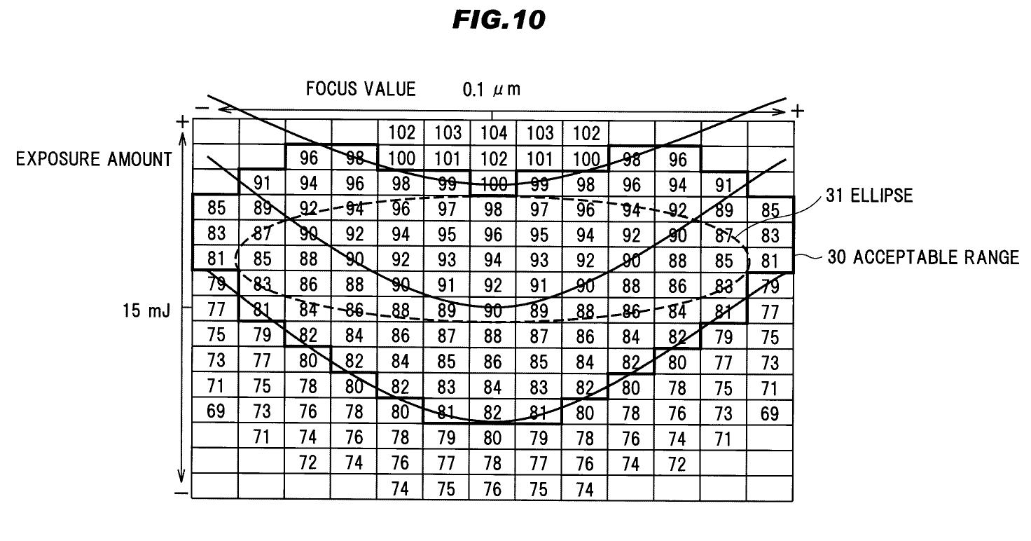

FIG. 10 is an explanatory view schematically showing an example of a calculating method of a wafer dimension W mm. Further, FIG. 10 is a three-dimensional graph having a lateral axis showing a focus value whose one section is specified to 0.05 μm and a longitudinal axis showing an exposure amount whose one section is specified to 0.5 mJ, and the three-dimensional graph shows a relationship between the focus value and exposure amount and the wafer pattern dimension data (width dimensions) Wwa, Wwb. The predetermined process conditions are specified to 0.1 μm of the focus value and 15 mJ of the exposure amount, and it is designed that the dimension data (width dimension) Wwa (90 nm) of the wafer pattern is obtained, the wafer pattern being formed by actually transferring a predetermined width dimension (for example, 105 nm in dimension) of the mask pattern on a wafer at the predetermined process conditions. Further, it is designed that the dimension data (width dimension) Wwb (69 to 104 nm) of the wafer pattern is obtained, the wafer pattern being formed by actually transferring the mask pattern on a wafer at process conditions where the focus value and exposure amount are changed. And, if the acceptable value is specified to ±10% of the design pattern dimension (90 nm), an acceptable range 30 (within the heavy-line frame) becomes 81 nm to 99 nm. In case of FIG. 10, the acceptable range 30 is transformed to the direction that the exposure amount is increased, in a region where the focus value is deviated from the central value, so that the width dimension of the wafer pattern of a target (the wafer target pattern) is specified to a value (for example, 92 nm or 94 nm) displaced from 90 nm of the design pattern dimension to the transformed side of the acceptable range 30.

Particularly, the ellipse 31 is configured to have a long axis formed of the focus value that is lager than the exposure amount in an amount of change, to have a short axis formed of the exposure amount that is smaller than focus value in an amount of change, and to be inscribed in the acceptable range 30, and the width dimension 94 nm at almost the center of the ellipse 31 is obtained. The width dimension 94 nm becomes the width dimension of the wafer target pattern. Namely, the wafer target pattern of the original width dimension 90 nm may deviate from the acceptable range 30 due to variation in process conditions, however, if the wafer target pattern is specified to 94 nm, it can be kept within the acceptable range of the ellipse 31 even if the process conditions fluctuate to some extent. Further, if necessary, the ellipse 31 can be configured to have a long axis formed of the exposure amount that is smaller than the focus value in an amount of change and to have a short axis formed of the focus value that is larger than the exposure amount in an amount of change. Furthermore, the shapes other than the ellipse 31 such as rectangular shape can be also used.

### (5) Generating Data Set

The data set generation part 5 imports the dimension data Wm from the mask dimension data memory part 2, the dimension data Wwa from the wafer dimension data memory part 3 and the dimension data Wwm from the target dimension data calculation part 4, and generates the first data set (Wwa, Wwm) for allowing the first NN 60A to learn and the second data set (Wwa, Wm) for allowing the second NN 60B to learn (S5).

### (6) Learning of First and Second NN

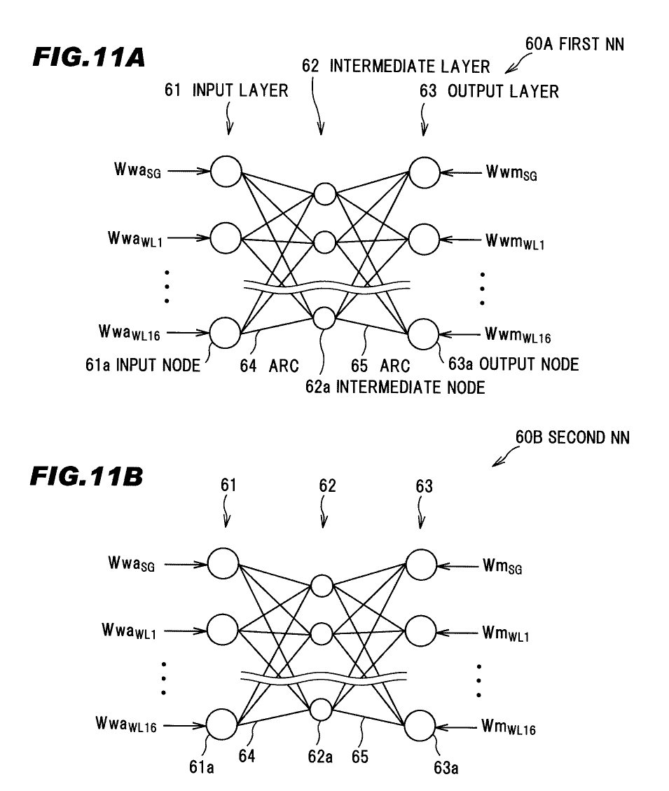

FIG. 11A is an explanatory view schematically showing a learning of the first NN and FIG. 11B is an explanatory view schematically showing a learning of the second NN.

As shown in FIG. 5, the data set generation part 5 inputs one dimension data Wwa (Wwa_{SG}, Wwa_{WL1} to Wwa_{WL16}) of the first data set (Wwa, Wwm) generated to nine (9) input nodes 61a of the first NN 60A respectively, and inputs another dimension data Wwm (Wwm_{SG}, Wwm_{WL1} to Wwm_{WL16}) to nine (9) output nodes 63a of the first NN 60A respectively, so as to allow the first NN 60A to learn.

Further, the data set generation part 5 inputs one dimension data Wwa (Wwa_{SG}, Wwa_{WL1} to Wwa_{WL16}) of the first data set (Wwa, Wm) generated to nine (9) input nodes 61a of the second NN 60B respectively, and inputs another dimension data Wm (WWm_{SG}, Wm_{WL1} to Wm_{WL16}) to nine (9) output nodes 63a of the second NN 60B respectively, so as to allow the second NN 60B to learn.

The first NN 60A sets a load value of the intermediate layer 62 so that the dimension data Wwm are outputted from the output layer 63 when the dimension data Wwa are inputted to the input layer 61. The second NN 60B sets a load value of the intermediate layer 62 so that the dimension data Wm are outputted from the output layer 63 when the dimension data Wwa are inputted to the input layer 61.

### (7) Predicting Optimum Mask Dimension

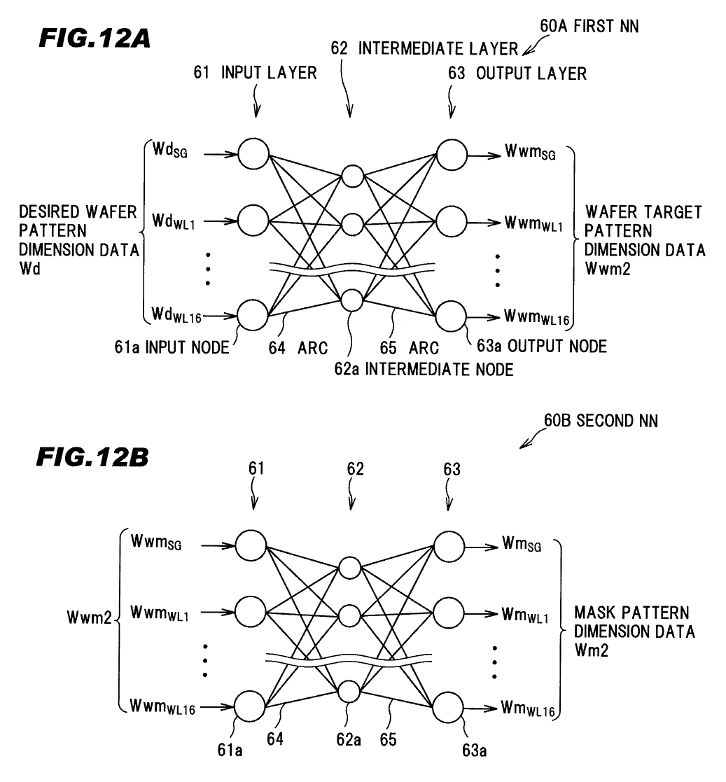

FIG. 12A is an explanatory view schematically showing a behavior of the first NN and FIG. 12B is an explanatory view schematically showing a behavior of the second NN. The control part 7 controls the neutral network processing part to operate in the operating mode.

As shown in FIG. 12A, the desired design dimension data Wd Wd (Wd_{SG}, Wd_{WL1} to Wd_{WL16}) are inputted to nine (9) input nodes 61a of the first input layer 61 of the first NN 60A respectively. The wafer target pattern dimension data Wwm2 (Wwm_{SG}, Wwm_{WL1} to Wwm_{WL16}) are outputted from nine (9) output nodes 63a of the first NN 60A respectively.

Next, as shown in FIG. 12B, the wafer target pattern dimension data Wwm2 (WWm_{SG}, Wwm_{WL1} to Wwm_{WL16}) outputted from the output layer 63 of the first NN 60A are inputted to the input nodes 61a of the second NN 60B respectively. The mask pattern dimension data Wm2 (Wm_{SG}, Wm_{WL1} to Wm_{WL16}) for forming the wafer target pattern at the predetermined process conditions are outputted from the output nodes 63a of the second NN 60B.

### Advantages of First Embodiment

According to the first embodiment, the following advantages are provided.

(1) The mask pattern dimension data for forming the wafer target pattern are obtained after the wafer target pattern dimension data are obtained so as to be kept within variation of the process conditions, so that the dimensions of the mask pattern where the variation of the process conditions is considered can be predicted.
(2) The neutral network is used, so that the mask pattern can be predicted with a high degree of accuracy.
(3) The first data set can be shown by a function simpler than that of the second data set (can be easily predicted), so that the data amount can be reduced in comparison with a case of using one NN, by that the first data set allows the first NN 60A to learn and the second data set allows the second NN 60B to learn separately.

### (Modification)

In the first embodiment, the mask pattern is used as “first pattern” and the wafer pattern is used as “second pattern”, but in the modification, the mask pattern is used as “first pattern” and the resist pattern is used as “second pattern”. Further, the pattern predicting device 1 according to the modification is basically the same as that shown in FIG. 1, so that it will be explained without showing by drawings.

The target dimension data calculation part 4 calculates the resist target pattern dimension data Wrm by using, for example, a general margin analytic tool, based on the dimension data Wra of N resist patterns formed by transferring on the resist at the predetermined process conditions and the dimension data Wrb of M resist patterns formed by transferring on the resist at process conditions different from the predetermined process conditions.

The data set generation part 5 generates first data set (Wra, Wrm) and second data set (Wra, Wm), at the learning mode, inputs the dimension data Wra to the input layer 61 of the first NN 60A and the dimension data Wrm to the output layer 63 at the time of the learning mode, and inputs the dimension data Wra to the input layer 61 of the second NN 60B and the dimension data Wm to the output layer 63. Further, the dimension data Wm is the mask pattern dimension data, similarly to the case of the embodiment.

When the desired resist pattern dimension data are inputted to the input layer 61 of the first NN 60A at the operation mode, the resist target pattern dimension data are outputted from the output layer 63, the resist target pattern dimension data are inputted to the input layer 61 of the second NN 60B, and the mask pattern dimension data Wm2 are obtained from the output layer 63.

According to the modification, the dimensions of the mask pattern where the variation of the process conditions is considered can be predicted from the desired resist pattern.

### Second Embodiment

The second embodiment shows a method of fabricating a semiconductor device by using the pattern predicting device and the pattern predicting method of the first embodiment. Namely, the semiconductor device such as the NAND type flash-memory is fabricated by obtaining the optimum mask pattern dimension data by using the pattern predicting device and the pattern predicting method of the first embodiment, forming a mask having the optimum mask pattern obtained, and forming a device pattern such as the circuit pattern shown in FIG. 4 on a wafer via the lithography process, the etching process and the like where the mask is used.

Further, it should be noted that the present invention is not intended to be limited to the above-mentioned embodiments and modification, and the various kinds of changes thereof can be implemented by those skilled in the art without departing from the gist of the invention.

For example, similarly to the above-mentioned embodiments and modification, after the dimensions of the actual mask pattern are predicted, the dimensions on the mask design data can be predicted from the predicted dimensions of the actual mask pattern by using the third neutral network. In this case, when the dimensions on the mask design data are predicted from the dimensions of the actual mask pattern, mask process tolerance can be considered or need not to be considered.

Further, it can be also adopted that the dimensions of the desired resist pattern are predicted from the dimensions of the desired design pattern by using the third neutral network, and later the mask pattern is predicted similarly to the case of the modification. In this case, when the dimensions of the desired resist pattern are predicted from the dimensions of the desired design pattern, etching process tolerance can be considered or need not to be considered.

Further, the resist pattern can be also formed on the wafer by using an electron beam direct imaging method where the mask is not used.

The program used in the above-mentioned embodiments and modification can be read into the memory of the device from the recording media such as CD-ROM, or can be downloaded onto the memory of the device from the server or the like connected to the network such as the internet.

What is claimed is:

1. A pattern predicting method, comprising:
obtaining shape data of a target pattern from shape data of a second pattern to be formed by transferring a first pattern at predetermined process conditions by using a first neutral network, the target pattern being to be a target of the second pattern when the first pattern is transferred at the predetermined process conditions, so as to keep the transferred patterns within an acceptable range, the transferred patterns being formed by transferring the first pattern at process conditions changed from the predetermined process conditions; and
obtaining shape data of a new first pattern for forming the target pattern at the predetermined process conditions by using a second neutral network.

2. The pattern predicting method according to claim 1, wherein:
the first pattern is a mask pattern; and
the second pattern is a wafer pattern or a resist pattern.

3. The pattern predicting method according to claim 2, wherein:
the process conditions include a focus value and a dose.

4. The pattern predicting method according to claim 1, wherein:
the shape data of the target pattern being to be a target of the second pattern are obtained so that process tolerance that the shape data of the second pattern are kept within the acceptable range even if the process conditions fluctuate becomes almost the largest value.

5. The pattern predicting method according to claim 3, wherein:
the shape data of almost a center of an ellipse inscribed in a region of the acceptable range of the shape data are obtained as the shape data of the target pattern being to be a target of the second pattern, the ellipse being inscribed in the region of the acceptable range when a relationship between the focus value and the dose, and the shape data of the second pattern and the shape data of the third pattern is shown by a three dimensional graph.

6. The pattern predicting method according to claim 3, wherein:
the ellipse has a long axis selected from either the focus value or the dose that is lager than another in an amount of change.

7. The pattern predicting method according to claim 1, wherein:
the first and second patterns are formed by that a plurality of line patterns are arranged in the width direction of the line pattern, and
the shape data include a width of the line pattern or a distance between the line patterns.

8. The pattern predicting method according to claim 7, wherein:
the plural line patterns include selection gate lines and word lines of a semiconductor device.

9. The pattern predicting method according to claim 1, wherein:
further, obtaining design data of the first pattern from the new first pattern by using a third neutral network.

10. The pattern predicting method according to claim 1, wherein: the method further comprises;
a first learning step of inputting the shape data of the plural second patterns formed by transferring the plural first patterns having different shapes at predetermined process conditions to an input layer of the first neutral network, obtaining the shape data of the plural target patterns based on the shape data of the plural second patterns and shape data of plural third patterns formed by transferring the plural first patterns at process conditions having at least one process condition different from the predetermined process conditions, and inputting the shape data of the plural target patterns to an output layer of the first neutral network so as to allow the first neutral network to learn, and;
a second learning step of inputting the shape data of the plural second patterns inputted to the input layer of the first neutral network in the first learning step to an input layer of the second neutral network, and inputting the shape data of the plural first patterns having different shapes in the first learning step to the output layer of the second neutral network so as to allow the second neutral network to learn.

11. The pattern predicting method according to claim 10, wherein:
the first pattern is a mask pattern; and
the second pattern is a wafer pattern or a resist pattern.

12. The pattern predicting method according to claim 11, wherein:
the process conditions include a focus value and a dose.

13. The pattern predicting method according to claim 1, wherein:
the shape data of the target pattern being to be a target of the second pattern are obtained so that process tolerance that the shape data of the second pattern are kept within the acceptable range even if the process conditions fluctuate becomes almost the largest value.

14. A computer-readable recording media comprising:
a computer program recorded thereon, wherein the computer program is configured to instruct a computer to execute;
obtaining shape data of a target pattern from shape data of a second pattern to be formed by transferring a first pattern at predetermined process conditions by using a first neutral network, the target pattern being to be a target of the second pattern when the first pattern is transferred at the predetermined process conditions, so as to keep the transferred patterns within an acceptable range, the transferred patterns being formed by transferring the first pattern at process conditions changed from the predetermined process conditions; and
obtaining shape data of a new first pattern for forming the target pattern at the predetermined process conditions.

15. The computer-readable recording media according to claim 14, wherein:
the first pattern is a mask pattern; and
the second pattern is a wafer pattern or a resist pattern.

16. The computer-readable recording media according to claim 14, wherein:
the process conditions include a focus value and a dose.

17. The computer-readable recording media according to claim 14, wherein:
the shape data of the target pattern being to be a target of the second pattern are obtained so that process tolerance that the shape data of the second pattern are kept within the acceptable range even if the process conditions fluctuate becomes almost the largest value.

18. The computer-readable recording media according to claim 14, wherein:
the shape data of almost a center of an ellipse inscribed in a region of the acceptable range of the shape data are obtained as the shape data of the target pattern being to be a target of the second pattern, the ellipse being inscribed in the region of the acceptable range when a relationship between the focus value and the dose, and the shape data of the second pattern and the shape data of the third pattern is shown by a three dimensional graph.

19. A method of fabricating a semiconductor device, comprising:
obtaining the data of the new first pattern by using the pattern predicting method according to claim 1; and
forming a device pattern on a wafer by using a mask having the new first pattern obtained.

20. A method of fabricating a semiconductor device according to claim 19, wherein:
the device further comprises a data set generation part for;
generating the shape data of the plural second patterns formed by transferring the plural first patterns having different shapes at predetermined process conditions, and the shape data of the plural target patterns based on the shape data of the plural second patterns and shape data of plural third patterns formed by transferring the plural first patterns at process conditions having at least one process condition different from the predetermined process conditions,
inputting the shape data of the plural second patterns to the input layer of the first neutral network,
inputting the shape data of the plural target patterns to the output layer of the first neutral network,
inputting the shape data of the plural second patterns to the input layer of the second neutral network, and
inputting the shape data of the plural first patterns to the output layer of the second neutral network.
